(19) United States
(12) Patent Application Publication
(10) Pub. No.: US 2026/0110730 A1
(43) Pub. Date: Apr. 23, 2026

(54) POWER SUPPLY CONTROL DEVICE

(71) Applicant: Denso Ten Limited, Kobe (JP)

(72) Inventors: Seiya MORIKAWA, Kobe (JP); Takeshi Matsumoto, Kobe (JP)

(73) Assignee: Denso Ten Limited, Kobe (JP)

(21) Appl. No.: 19/364,419

(22) Filed: Oct. 21, 2025

(30) Foreign Application Priority Data
Oct. 22, 2024 (JP) 2024-186039
Nov. 20, 2024 (JP) 2024-202189
Jul. 31, 2025 (JP) 2025-127880

(51) Int. Cl. G01R 31/28; B60R 16/03

(52) U.S. Cl. CPC G01R 31/2834; B60R 16/03

(57) ABSTRACT

An in-vehicle control device, for a normally-off type inter-system switch disposed between a first system and a second system, includes: a driver configured to output an ON or OFF signal to the inter-system switch; and a computer configured to perform self-reset operation check upon an ignition ON of a vehicle, then to initiate supplying a power supply voltage and outputting the ON signal to the driver, upon completion of the self-reset operation check.

### CROSS-REFERENCE TO RELATED APPLICATIONS

This application is based upon and claims the benefit of priority from prior Japanese patent application No. 2024-186039 filed on Oct. 22, 2024, Japanese patent application No. 2024-202189 filed on Nov. 20, 2024, and Japanese patent application No. 2025-127880 filed on Jul. 31, 2025, the entire contents of which are incorporated herein by reference.

### TECHNICAL FIELD

The present disclosure relates to an in-vehicle control device.

### BACKGROUND ART

A redundant power supply system including an inter-system line that connects a first system that supplies electric power of a first power supply to a first load and a second system that supplies electric power of a second power supply to a second load has been known (for example, see JP2022-111637A).

In JP2022-111637A, by using a normally-off type inter-system switch, the inter-system switch is set to be maintained in a turning-off state even when electric power for driving the inter-system switch is not supplied while an ignition (hereinafter, IG) is turned off. Then, there is disclosed a technique of preventing electric power consumption for turning off the inter-system switch by setting the inter-system switch to be maintained in the turning-off state in this manner. In addition, JP2022-111637A discloses a technique in which a control unit controls a switch provided in each system to control power supply to a load.

### SUMMARY OF INVENTION

When a computer such as a microcomputer is used as the control unit disclosed in JP2022-111637A, reset confirmation processing for confirming whether the computer can normally perform a reset operation after system startup is required. When the reset confirmation processing is performed in this manner, the computer cannot perform controls while the computer is being reset. Therefore, the inter-system switch cannot be controlled while the computer is being reset, and there is a possibility that a turning-on/off state of the inter-system switch is switched during the reset confirmation processing and before and after the reset confirmation processing. When the number of times the inter-system switch is turned on/off unnecessarily increases during initialization processing, there is a concern that the inter-system switch may deteriorate earlier.

Aspects of the present disclosure relate to providing an in-vehicle control device capable of preventing an inter-system switch from deteriorating early.

According to an aspect of the present disclosure, there is provided an in-vehicle control device, for a normally-off type inter-system switch disposed between a first system and a second system, including: a driver configured to output an ON or OFF signal to the inter-system switch; and a computer configured to perform self-reset operation check upon an ignition ON of a vehicle, then to initiate supplying a power supply voltage and outputting the ON signal to the driver upon completion of the self-reset operation check.

According to aspects of the present disclosure, the computer starts supplying a power supply voltage to a driver after the reset confirmation processing, so that the inter-system switch is not driven by the driver until the reset confirmation processing is completed. Therefore, the turning-on/off state of the inter-system switch is not switched during the reset confirmation processing and before and after the reset confirmation processing. That is, according to the present disclosure, since the number of times the inter-system switch is turned on/off does not increase even if the reset confirmation processing is performed, it is possible to prevent the inter-system switch from deteriorating early.

### BRIEF DESCRIPTION OF DRAWINGS

Exemplary embodiment(s) of the present invention will be described in detail based on the following figures, wherein:

FIG. 1 is a diagram illustrating a configuration and an operation of a power supply control device according to an embodiment;

FIG. 2 is a diagram illustrating the configuration and the operation of the power supply control device according to the embodiment;

FIG. 3 is a diagram illustrating the configuration and the operation of the power supply control device according to the embodiment;

FIG. 4 is a diagram illustrating the configuration and the operation of the power supply control device according to the embodiment;

FIG. 5 is a diagram illustrating the operation of the power supply control device immediately after an IG is turned on;

FIG. 6 is a diagram illustrating a configuration example of a power supply circuit;

FIG. 7 is a diagram illustrating another configuration example of the power supply circuit;

FIG. 8 is a timing chart illustrating operation timings of the power supply control device immediately after the IG is turned on;

FIG. 9 is a diagram illustrating a power supply control device according to a modification;

FIG. 10 is a diagram illustrating the power supply control device according to the modification;

FIG. 11 is a diagram illustrating the power supply control device according to the modification;

FIG. 12 is a diagram illustrating a power supply control device according to a modification;

FIG. 13 is a diagram illustrating a power supply control device according to a modification; and

FIG. 14 is a diagram illustrating a power supply control device according to a modification.

### DESCRIPTION OF EMBODIMENTS

Hereinafter, a power supply control device as an in-vehicle control device according to an embodiment will be described in detail with reference to the accompanying drawings. The present disclosure is not limited to the following embodiment. Hereinafter, a case where a vehicle on which the power supply control device according to the embodiment is mounted is an electric vehicle or a hybrid vehicle will be described. A power supply control device according to the embodiment is a redundant power supply device that is mounted on a vehicle mainly including an autonomous driving function, and is intended to supply electric power to a load that requires power supply even when a failure of a main power supply occurs mainly during autonomous driving.

The vehicle on which the power supply control device according to the embodiment is mounted may be an engine automobile that travels using an internal combustion engine.

### Configuration of Power Supply Control Device

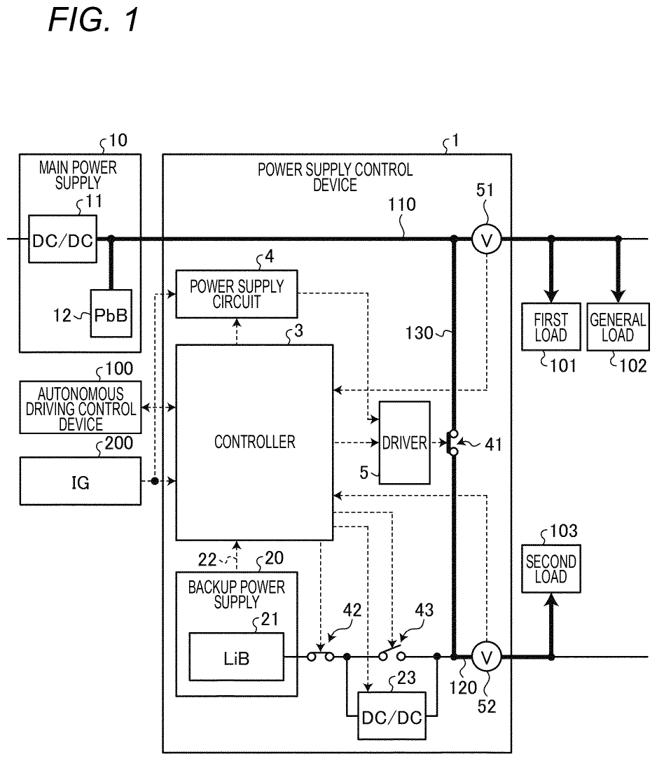

A configuration and an operation of a power supply control device 1 according to the embodiment will be described with reference to FIGS. 1 to 4. FIGS. 1 to 4 are diagrams illustrating the configuration and the operation of the power supply control device 1 according to the embodiment.

As illustrated in FIG. 1, the power supply control device 1 according to the embodiment is connected to a main power supply 10, a first load 101, a general load 102, a second load 103, an autonomous driving control device 100, and an IG 200.

The power supply control device 1 includes a first system 110 and a second system 120. The first system 110 is a power supply system that supplies electric power from the main power supply 10 to the first load 101 and the general load 102. The second system 120 is a power supply system that supplies, to the second load 103, electric power from a backup power supply 20 to be described later. The main power supply 10 is a first power supply, and the backup power supply 20 is a second power supply.

The first load 101 includes a load for autonomous driving. The first load 101 includes a steering motor that operates during the autonomous driving, an electric brake device, an in-vehicle camera, and the like. The general load 102 is a load that is not directly involved in automatic driving, and includes a display, an air conditioner, audio, video, and various lights.

The second load 103 has a part of an autonomous driving function of the first load 101. The second load 103 includes devices required at the minimum for a fail-operational control (retreat travel control), such as a steering motor, an electric brake device, and a radar. The first load 101, the general load 102, and the second load 103 operate with electric power supplied from the power supply control device 1.

The autonomous driving control device 100 is a device that performs an autonomous driving control of the vehicle by operating the first load 101 and the second load 103. When a power supply failure such as a ground fault occurs in the first system 110 during the autonomous driving of the vehicle, the autonomous driving control device 100 may perform the fail-operational control using the second load 103. When a power supply failure such as a ground fault occurs in the second system 120, the autonomous driving control device 100 may perform the fail-operational control using the first load 101.

Specifically, when a power supply failure occurs during the autonomous driving, the autonomous driving control device 100 performs the retreat travel control of the vehicle and causes the vehicle to travel to a safe place and stop. When the retreat travel is normally completed, the autonomous driving control device 100 transmits a retreat travel completion notification indicating the completion to the power supply control device 1.

The IG 200 is an ignition key for starting up the vehicle (system). When the vehicle is started by an ignition key, the IG 200 outputs an IG ON signal to the power supply control device 1. The IG ON signal (or may be referred to as an IG signal) is an example of a system signal (system startup signal).

The main power supply 10 includes a DC/DC converter (hereinafter, referred to as “DC/DC 11”) and a lead battery (hereinafter, referred to as “PbB 12”). The battery of the main power supply 10 may be any secondary battery (for example, a lithium ion battery) other than the PbB 12. The main power supply 10 is an example of the first power supply.

The DC/DC 11 is connected to a high-voltage battery. The DC/DC 11 steps down a voltage of the high-voltage battery and outputs the stepped-down voltage to the first system 110. In a case of a hybrid vehicle, a generator (not illustrated) is connected to the first system 110. The generator is an alternator that generates electric power by converting kinetic energy of an engine into electricity. The high-voltage battery is a battery having a higher voltage than the PbB 12, and is a battery for driving a vehicle (for driving a traveling motor) mounted on an electric vehicle or a hybrid vehicle. The DC/DC 11 charges the PbB 12, supplies electric power to the first load 101 and the general load 102, supplies electric power to the second load 103, and charges the backup power supply 20 to be described later.

In a case where the main power supply 10 is mounted on an engine automobile, the generator (alternator) is provided instead of the DC/DC 11.

The power supply control device 1 includes the backup power supply 20, an inter-system switch 41, a system relay 42, a battery switch 43, a controller 3, a power supply circuit 4, a driver 5, a first voltage sensor 51, a second voltage sensor 52, and a DC-DC converter (DC/DC) 23). The backup power supply 20 is a backup power supply when the main power supply 10 cannot supply the electric power. The backup power supply 20 includes a lithium-ion battery (hereinafter, referred to as “LiB 21”). A battery of the backup power supply 20 may be any secondary battery other than the LiB 21.

The inter-system switch 41 is provided in an inter-system line 130 that connects the first system 110 and the second system 120. The inter-system switch 41 is a switch capable of connecting and cutting off the first system 110 and the second system 120. The inter-system switch 41 is a normally-off type switch in which the state of the switch is in a turning-off state when the power supply is turned off (IG OFF), in other words, when a signal for controlling the state of the switch (a drive signal to be described later) is not input. Therefore, the inter-system switch 41 is in a turning-off state in a state in which a drive signal for a switching control (a signal for controlling switching) is not input from the driver 5. The inter-system switch 41 is turned on when a drive signal for turning on is input from the driver 5, and is turned off when the drive signal for turning on is not input from the driver 5.

The inter-system switch 41 is implemented by, for example, a semiconductor switch such as a field effect transistor (FET). When the inter-system switch 41 is implemented by the FET, the drive signal from the driver 5 is an ON/OFF signal input to a gate of the FET. The turning-on state or the turning-off state is a state in which a voltage between the gate and a source is equal to or higher than a threshold (ON) or is lower than the threshold (OFF).

In the present embodiment, electrically connecting the first system 110 and the second system 120 by the inter-system switch 41 is referred to as conducting the inter-system switch 41 or turning on the inter-system switch 41.

In the present embodiment, disconnecting the electrical connection between the first system 110 and the second system 120 by the inter-system switch 41 is referred to as cutting off the inter-system switch 41 or turning off the inter-system switch 41.

The system relay 42 is a switch that connects the backup power supply 20 to the second system 120. In the embodiment, electrically connecting between the backup power supply 20 and the second system 120 by the system relay 42 is referred to as conducting the system relay 42 or turning on the system relay 42.

In the present embodiment, disconnecting the electrical connection between the backup power supply 20 and the second system 120 by the system relay 42 is referred to as cutting off the system relay 42 or turning off the system relay 42. The system relay 42 is controlled to be in a turning-on state when the power supply control device 1 is in a state of being started up, such as when the IG 200 is turned on.

The battery switch 43 is a switch that connects the system relay 42 and the second system 120. The battery switch 43 is normally turned off, and is turned on when power supply from the backup power supply 20 is required. The DC/DC 23 is connected in parallel with the battery switch 43 and adjusts the voltage input from the main power supply 10 to the LiB 21 during charging (when the battery switch 43 is turned off).

The first voltage sensor 51 is provided in the first system 110. The first voltage sensor 51 detects a voltage of the first system 110 and outputs a detection result to the controller 3. The second voltage sensor 52 is provided in the second system 120. The second voltage sensor 52 detects a voltage of the second system 120 and outputs a detection result to the controller 3.

The controller 3 is a computer such as a microcomputer having a central processing unit (CPU), a read only memory (ROM), a random access memory (RAM), and the like.

The controller 3 controls an operation of the power supply control device 1 by the CPU executing a program stored in the ROM by using the RAM as a work area. That is, the controller 3 performs a basic control by software processing. The controller 3 controls the power supply circuit 4, the driver 5, the inter-system switch 41, the system relay 42, the battery switch 43, and the DC/DC 23. Note that the DC/DC 11 may also be controlled.

The controller 3 acquires a state value indicating a charging state of the backup power supply 20 from the backup power supply 20 via a state monitoring line 22. The state value indicating the charging state of the backup power supply 20 is, for example, a state of charge (SOC) of the LiB 21.

The LiB 21 is in a state in which a remaining charge amount is maximum when the SOC is 100%. The LiB 21 is in a state in which there is no remaining charge amount when the SOC is 0%. The controller 3 acquires, for example, the SOC of the LiB 21 as the state value indicating the charging state of the backup power supply 20. The controller 3 monitors the remaining charge amount of the backup power supply 20 based on the SOC of the LiB 21.

The controller 3 detects a failure of the main power supply 10 (the first system 110) or the backup power supply 20 (the second system 120) based on the detection results input from the first voltage sensor 51 and the second voltage sensor 52. For example, the controller 3 detects a failure of the first system 110 or the second system 120. The failure of the main power supply 10 includes a ground fault of the first system 110 and disconnection or a short circuit of the first system 110. The failure of the backup power supply 20 includes a ground fault of the second system 120 and disconnection or a short circuit of the first system 110. When the failure of the first system 110 or the second system 120 is detected, the controller 3 notifies the autonomous driving control device 100 of the detection.

Specifically, when a failure of the main power supply 10 or the backup power supply 20 is detected, the controller 3 outputs, to the autonomous driving control device 100, an autonomous driving prohibition signal indicating that autonomous driving is disabled. When a failure of the main power supply 10 or the backup power supply 20 is not detected, the controller 3 outputs, to the autonomous driving control device 100, an autonomous driving permission signal indicating that autonomous driving is enabled.

When a failure of the main power supply 10 or the backup power supply 20 is detected, the controller 3 causes a nonvolatile memory to store diagnosis information indicating the detection. In a case where the diagnosis information is stored in the nonvolatile memory at next startup, the controller 3 prohibits autonomous driving by the autonomous driving control device 100.

Specifically, the controller 3 prohibits the autonomous driving by the autonomous driving control device 100 by outputting, to the autonomous driving control device 100, the autonomous driving prohibition signal indicating that the autonomous driving is disabled. Accordingly, the power supply control device 1 may prevent the autonomous driving from being erroneously performed by the autonomous driving control device 100 even though the failure of the main power supply 10 or the backup power supply 20 is not resolved at the next startup after the retreat travel is completed. The autonomous driving control device 100 performs the retreat travel when the autonomous driving prohibition signal is input from the controller 3, that is, when the controller 3 detects a power supply failure. The retreat travel is to retreat to a retreat position by autonomous driving in which a traveling control function is limited or manual driving by the driver. Note that, as a function of autonomous driving prohibited based on the autonomous driving prohibition signal, a function of autonomous driving required for retreat travel is excluded.

The power supply circuit 4 generates and supplies a power supply voltage for driving the inter-system switch 41. Specifically, the power supply circuit 4 can generate a first power supply voltage and a second power supply voltage. The first power supply voltage is generated based on a first clock generated by the controller 3. The second power supply voltage is generated based on a second clock generated by a clock generation circuit 413 separate from the controller 3 when the IG ON signal input from the IG 200 is input. Details of this point will be described later. The power supply circuit 4 outputs the generated power supply voltage to the driver 5.

The driver 5 is a drive circuit that drives the inter-system switch 41. The driver 5 controls the inter-system switch 41 based on a control signal output from the controller 3 in a state in which a power supply voltage (driving electric power) is input from the power supply circuit 4. The driver 5 is configured to output an ON or OFF signal to the inter-system switch 41. Specifically, when an ON signal is input from the controller 3 in a state in which the power supply voltage is input, the driver 5 turns on the inter-system switch 41. When an OFF signal is input from the controller 3 in a state in which the power supply voltage is input, the driver 5 turns off the inter-system switch 41.

Next, a basic operation of the power supply control device 1 will be described with reference to FIGS. 1 to 4.

### Normal Operation of Power Supply Control Device

First, a normal operation will be described with reference to FIG. 1. The controller 3 controls the inter-system switch 41, the system relay 42 and the battery switch 43 as illustrated in FIG. 1 at a normal time when no failure occurs in the main power supply 10 and the backup power supply 20. Specifically, the controller 3 turns on the system relay 42, cuts off the battery switch 43, and turns on the inter-system switch 41. Accordingly, the electric power is supplied from the main power supply 10 to the first load 101, the general load 102, and the second load 103. The controller 3 outputs the autonomous driving permission signal to the autonomous driving control device 100 at the normal time when no failure occurs in the main power supply 10 and the backup power supply 20.

### Operation of Power Supply Control Device When Power Supply Failure Occurs

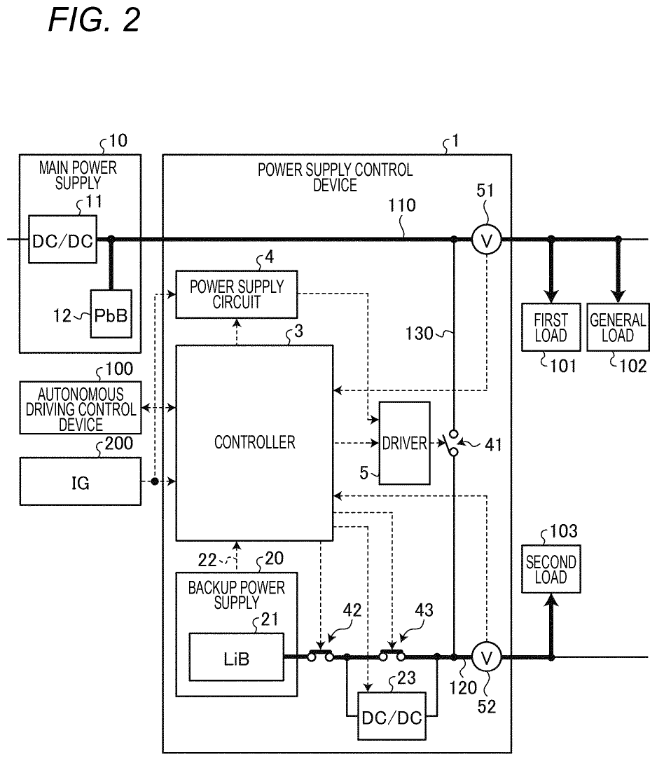

Next, an operation of the power supply control device 1 when a power supply failure occurs will be described with reference to FIGS. 2 to 4. The controller 3 detects the occurrence of a power supply failure by comparing a parameter related to the failure of the first system 110 or the second system 120 with a threshold.

Here, a case where the parameter related to the failure of the main power supply 10 is the voltage of the first system 110 and the parameter related to the failure of the backup power supply 20 is the voltage of the second system 120 will be described. Hereinafter, the voltage of the first system 110 detected by the first voltage sensor 51 will be referred to as a first system voltage V1. The voltage of the second system 120 detected by the second voltage sensor 52 is referred to as a second system voltage V2.

The parameter related to the failure of the main power supply 10 may be a current flowing through the first system 110 or a current flowing through the second system 120. In this case, the power supply control device 1 includes a current sensor that detects the current flowing through the first system 110 and a current sensor that detects the current flowing through the second system 120. When the current flowing through the first system 110 or the current flowing through the second system 120 exceeds an overcurrent threshold, the controller 3 detects occurrence of a ground fault.

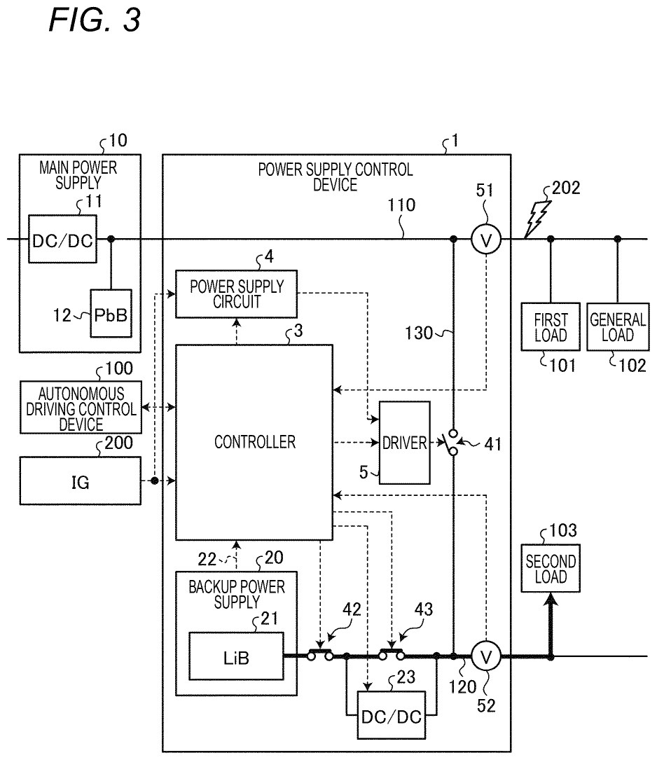

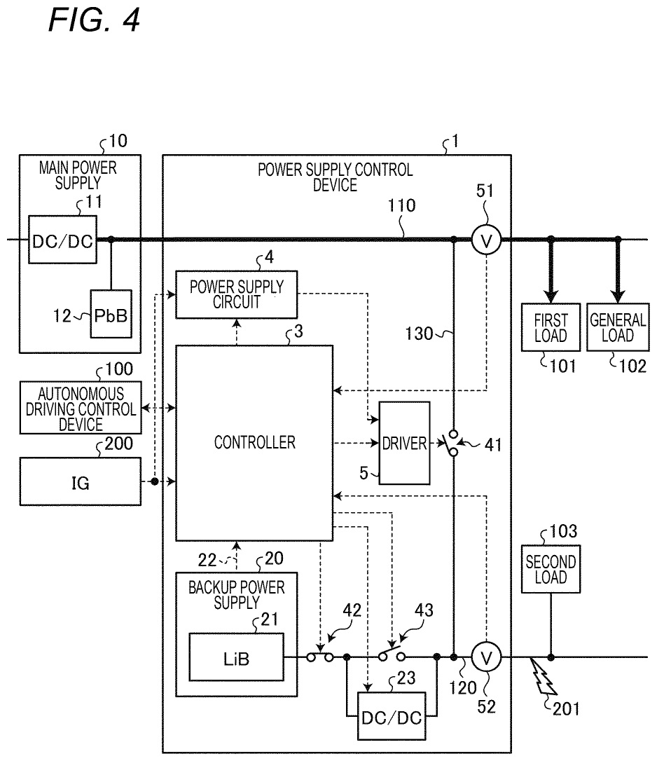

In the power supply control device 1, when a ground fault 202 occurs in the first system 110 (see FIG. 3), or when a ground fault 201 occurs in the second system 120 (see FIG. 4), an overcurrent flows toward a ground fault point, for example. Therefore, the first system voltage V1 and the second system voltage V2 become equal to or lower than a ground fault threshold.

When the first system voltage V1 and the second system voltage V2 is equal to or lower than the ground fault threshold, the controller 3 temporarily determines that the ground fault 202 or the ground fault 201 occurs in the first system 110 or the second system 120. Thereafter, the controller 3 outputs the autonomous driving prohibition signal to the autonomous driving control device 100.

When it is temporarily determined that the ground fault 202 or the ground fault 201 occurs, the controller 3 turns off the inter-system switch 41 and turns on the battery switch 43. The system relay 42 is maintained in the turning-on state. Accordingly, when the connection between the first system 110 and the second system 120 is cut off, electric power is supplied from the main power supply 10 to the first system 110, and electric power is supplied from the backup power supply 20 to the second system 120. Hereinafter, the cutting off of the inter-system switch 41 based on a result of the temporary determination is also referred to as pre-cutoff.

When at least one of the first system voltage V1 and the second system voltage V2 is equal to or lower than the ground fault threshold, the controller 3 may temporarily determine that a ground fault occurs in the first system 110 or the second system 120.

The temporary determination may be performed by a hard circuit having a comparator. In this case, the comparator compares the second system voltage V2 with the ground fault threshold. When the detected voltage is equal to or lower than the ground fault threshold, the comparator turns off the inter-system switch 41 and turns on the battery switch 43 by outputting a failure detection signal indicating the temporary determination.

Subsequently, after temporarily determining that a ground fault occurs in the first system 110 or the second system 120, the controller 3 performs a main determination of determining the system in which the ground fault occurs. When the controller 3 turns off the inter-system switch 41 and turns on the system relay 42 and the battery switch 43 in the pre-cutoff, a system voltage of the system in which the ground fault does not occur returns to a normal state, and a system voltage of the system in which the ground fault occurs continues to decrease.

When the first system voltage V1 is equal to or lower than the ground fault threshold continuously for a predetermined period or longer and the second system voltage V2 returns to be equal to or higher than a normal threshold that is larger than the ground fault threshold continuously for a predetermined period or longer after the pre-cutoff, the controller 3 confirms that the second system 120 is normal and the ground fault 202 occurs in the first system 110. The predetermined period here is, for example, 100 ms. The predetermined period is not limited to 100 ms. The normal threshold is a value larger than the ground fault threshold.

In a case where it is confirmed that the ground fault 202 occurs in the first system 110, as illustrated in FIG. 3, the controller 3 performs a fail-safe control for supplying electric power from the backup power supply 20 to the second load 103, and notifies the autonomous driving control device 100 of this fact. Accordingly, the autonomous driving control device 100 may operate the second load 103 with the electric power supplied from the backup power supply 20 to cause the vehicle to retreat to a safe place and stop. The fail-safe control may include cutting off of the inter-system switch 41 by the temporary determination, conduction of the battery switch 43, and notification to the autonomous driving control device 100 at the time of the confirmation.

When the first system voltage V1 returns to be equal to or higher than the normal threshold continuously for a predetermined period or longer and the second system voltage V2 is equal to or lower than the ground fault threshold continuously for a predetermined period or longer after the pre-cutoff, the controller 3 confirms that the first system 110 is normal and that the ground fault 201 occurs in the second system 120.

In a case where it is confirmed that the ground fault 201 occurs in the second system 120, the controller 3 performs the fail-safe control in which the battery switch 43 is turned off and the electric power from the main power supply 10 is supplied to the first load 101 and the general load 102, as illustrated in FIG. 4. The controller 3 notifies the autonomous driving control device 100 of this fact. Accordingly, the autonomous driving control device 100 may operate the first load 101 with the electric power supplied from the main power supply 10 to cause the vehicle to retreat to a safe place and stop.

When both the first system voltage V1 and the second system voltage V2 return to equal to or higher than the normal threshold continuously for the predetermined period or longer after the pre-cutoff, the controller 3 determines that the voltages only temporarily decreased and neither the ground fault 202 nor 201 occurs. That is, the controller 3 confirms both the first system 110 and the second system 120 are in their normal states.

In this case, the controller 3 turns off the battery switch 43 from a pre-cutoff state illustrated in FIG. 2, turns on the inter-system switch 41, and returns to a normal operation state illustrated in FIG. 1. Accordingly, the controller 3 may prevent an amount of electric power stored in the backup power supply 20 from decreasing.

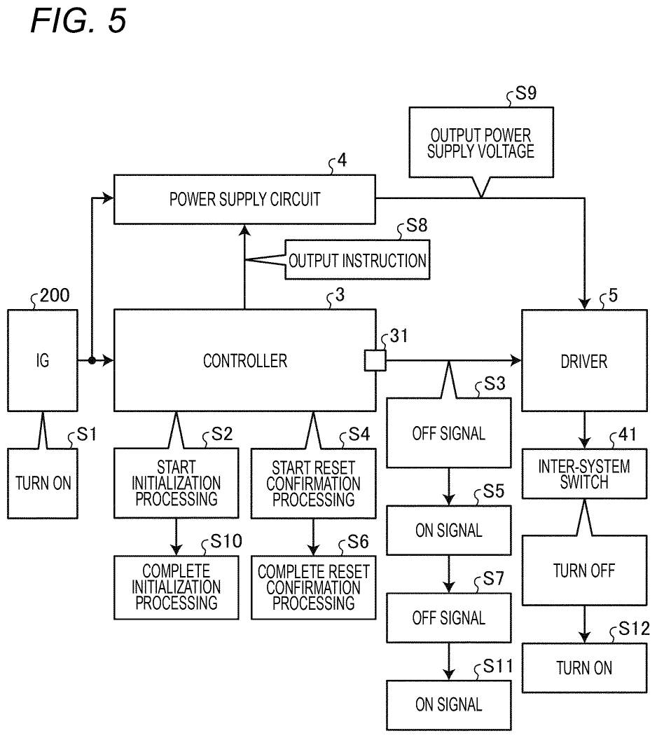

Next, the operation of the power supply control device 1 immediately after the IG 200 is turned on will be described with reference to FIG. 5. FIG. 5 is a diagram illustrating the operation of the power supply control device 1 immediately after the IG 200 is turned on. After the IG 200 is turned on, the power supply control device 1 performs initialization processing and reset confirmation processing (self-reset operation check). The initialization processing is processing of initializing the states of various systems, and includes, for example, startup processing of a microcomputer and an initial check performed at the startup. For example, a preliminary check of an abnormality detection function such as writing of initial data for control of a controller (computer) and an initial check, a sticking check of each switch (relay), and a drive operation check of a switch during a backup operation are performed. The reset confirmation processing is processing (self-reset operation check) of confirming whether the controller 3 itself can normally perform the reset operation (self-reset) when an abnormality of the controller 3 is detected. The initialization processing is performed when the IG 200 is turned on and the controller 3 is started up. The reset confirmation processing is performed while the initialization processing is being performed. That is, the controller 3 suspends the initialization processing, performs the reset confirmation processing, and resumes the initialization processing when the reset confirmation processing ends.

Here, when a computer such as a microcomputer is used as the control unit disclosed in JP2022-111637A, the reset confirmation processing for confirming whether the computer can normally perform a reset operation after system startup is required. When the reset confirmation processing is performed in this manner, the computer cannot perform a control while the computer is being reset. Therefore, while the computer is being reset, an ON signal set by default is output from a drive port that outputs a signal for controlling the inter-system switch. Basically, it is assumed that the computer is reset when an abnormality occurs in the computer during traveling or the like. Therefore, when the computer is reset, the inter-system switch is required to be on a safety side, such that the power supply to the load is maintained. Therefore, the drive port of the computer that controls the inter-system switch is set to a default setting in which a signal for controlling the inter-system switch to be turned on is output even while the computer is being reset. The computer performs the initialization processing for initializing the states of various systems at the time of startup after IG. Since various diagnosis processing is performed in this initialization processing, the reset confirmation processing described above is also performed. During the initialization processing, a large current may flow if there is an abnormality in a component during the diagnosis processing. When the inter-system switch is connected in a case where a large current flows in this way, a range in which the large current flows via the inter-system switch is widened, and a range in which a failure may occur due to the large current is widened. Therefore, during the initialization processing, the inter-system switch is controlled to be turned off. However, although it is desired to control the inter-system switch to be turned off during the initialization processing, when the reset confirmation processing is performed during the initialization processing, the inter-system switch is temporarily turned on as described above. As described above, when the number of times the inter-system switch is turned on/off unnecessarily increases during the initialization processing, there is a concern that the inter-system switch may deteriorate earlier.

Therefore, in the present disclosure, the power supply control device 1 outputs (supplies) the power supply voltage output from the power supply circuit 4 after the reset confirmation processing, so that the number of times the inter-system switch 41 is unnecessarily turned on/off can be reduced, and it is possible to prevent the inter-system switch 41 from deteriorating early. This point will be described below with reference to FIG. 5.

As illustrated in FIG. 5, first, when the IG 200 is turned on (step S1), the controller 3 starts up, and the controller 3 starts the initialization processing (step S2). When the initialization processing is started, the controller 3 outputs an OFF control signal (OFF signal) for turning off the inter-system switch 41 to the driver 5 from a drive port 31 that is an output port provided in the controller 3 and drives the inter-system switch 41 (step S3). That is, until the initialization processing is completed, the redundant power supply is still preparing to perform its original processing, the vehicle does not start traveling immediately after the IG 200 is turned on, the power supply to the load is basically unnecessary, and therefore the controller 3 performs a control not to connect the inter-system switch. Specifically, the drive port 31 of the controller 3 is set to output, to the driver 5, the OFF signal having a potential that maintains the inter-system switch 41 in the turning-off state during the initialization processing. In other words, the controller 3 sets the drive port 31 to a potential that maintains the inter-system switch 41 in the turning-off state.

On the other hand, since the power supply circuit 4 does not receive the notification of an output instruction of the power supply voltage from the controller 3 at a start time point of the initialization processing, the power supply circuit 4 does not output the power supply voltage to the driver 5. Therefore, since the power supply voltage is not input to the driver 5, the driver 5 cannot output the drive signal even if the OFF signal is input from the controller 3. Therefore, the inter-system switch 41 cannot be driven. As a result, the normally-off type inter-system switch 41 is maintained in the turning-off state.

Subsequently, the controller 3 starts the reset confirmation processing while performing the initialization processing (step S4). Specifically, the controller 3 performs a reset operation of resetting itself. When the reset operation is started, the drive port 31 of the controller 3 outputs an ON control signal (ON signal) for turning on the inter-system switch 41 to the driver 5 (step S5). Specifically, the drive port 31 of the controller 3 is set to output, to the driver 5, the ON signal having a potential that maintains the inter-system switch 41 in the turning-on state during the reset operation. This is to set the inter-system switch 41 to the safety side (turning-on state) when the controller 3 performs the reset operation. That is, in a case where the reset operation is required at the normal time (mainly, at the time of vehicle traveling such as autonomous driving) illustrated in FIG. 1, the inter-system switch 41 can be maintained in the turning-on state even when the controller 3 performs the reset operation, and thus it is possible to prevent the power supply to the second load 103 from being interrupted.

In FIG. 5, the power supply circuit 4 has not yet output the power supply voltage to the driver 5 even at a time point of step S5. Therefore, since the power supply voltage is not input to the driver 5, the driver 5 cannot drive the inter-system switch 41 in the turning-on state even when the ON signal is input from the controller 3. As a result, the normally-off type inter-system switch 41 is maintained in the turning-off state.

When the controller 3 confirms that the restart is completed by the reset operation and the reset operation is normally performed, the controller 3 completes the reset confirmation processing (step S6). Further, after the reset confirmation processing is completed, the controller 3 resumes the initialization processing and outputs the OFF signal from the drive port 31 (step S7).

After the reset confirmation processing is completed, the controller 3 notifies the power supply circuit 4 of the output instruction of the power supply voltage (step S8). The output instruction is, for example, a clock (the first clock) for the power supply circuit 4 to generate the power supply voltage, or a signal instructing start of an operation of the clock generation circuit 413 provided in the power supply circuit 4. Accordingly, the power supply circuit 4 generates the power supply voltage and outputs the power supply voltage to the driver 5 (step S9).

At a time point of step S9, the driver 5 outputs the drive signal for turning off the inter-system switch 41 because the OFF control signal (OFF signal) is input from the controller 3 in a state in which the power supply voltage is input from the power supply circuit 4 (see step S7). That is, since the inter-system switch 41 is already in the turning-off state, the turning-off state is maintained by the driving of the driver 5.

Thereafter, the controller 3 completes the initialization processing (step S10). When the initialization processing is completed, the controller 3 outputs the ON control signal (ON signal) from the drive port 31 to the driver 5 in order to shift to the normal operation illustrated in FIG. 1 (step S11).

As a result, since the ON control signal is input from the controller 3 in a state in which the power supply voltage is input from the power supply circuit 4 (see step S9), the driver 5 outputs the drive signal for turning on the inter-system switch 41. That is, the inter-system switch 41 is switched from the turning-off state to the turning-on state (step S12).

As described above, according to the present disclosure, since the power supply circuit 4 outputs the power supply voltage to the driver 5 after the reset confirmation processing, the power supply voltage is not supplied to the driver 5 during the reset confirmation processing.

Therefore, although the drive port 31 of the controller 3 outputs the ON signal to make the drive port 31 to be on the safe side during the reset confirmation processing, the power supply voltage is not supplied to the driver 5, and thus the inter-system switch 41 is not turned on. Therefore, the inter-system switch 41 is maintained in the turning-off state even if the reset confirmation processing is performed during the initialization processing. That is, according to the present disclosure, since the turning-off state is kept without being in the turning-on state even during the reset confirmation processing, the number of times the inter-system switch 41 is turned on/off does not increase, and thus it is possible to prevent the inter-system switch 41 from deteriorating early.

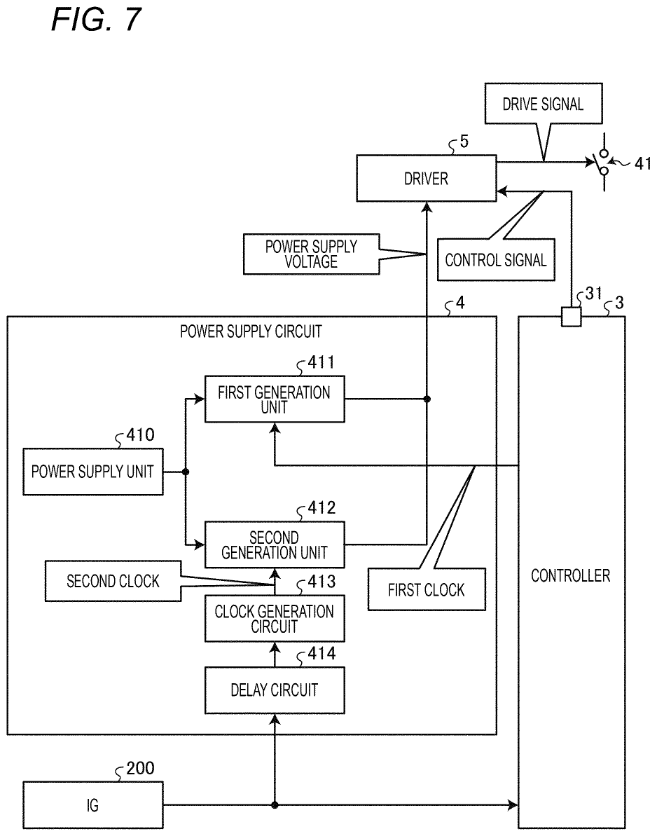

Among the control signals output from the controller 3, the control signals of steps S3 (OFF signal), S7 (OFF signal), and S11 (ON signal) are subjected to an output control by software processing of the controller 3. For example, an output value (ON/OFF) is set in an output register of the drive port 31 by software processing of the microcomputer (controller 3). Then, a hardware unit (input/output unit) of the microcomputer outputs the control signal of the output value set in the output register from the drive port. The control signal of step S5 (ON signal) is subjected to the output control by the hardware unit of the controller 3 because the controller 3 cannot perform the software processing during reset. For example, when the hardware unit (input/output unit) of the microcomputer detects that the microcomputer is being reset, the hardware unit outputs, from the drive port 31, a control signal having an output value (ON) set by default, instead of the value set in the output register. The control of the output instruction output from the controller 3 in step S8 is performed by the hardware unit of the controller 3. The control of the output instruction can be realized by, for example, a configuration in which a circuit having the same function as that of a delay circuit 414 (see FIG. 7) to be described later is provided in the controller 3, or a configuration in which a circuit configured to perform the output instruction when the reset completion is detected after the IG 200 changes from the turning-off state to the turning-on state is provided in the controller 3.

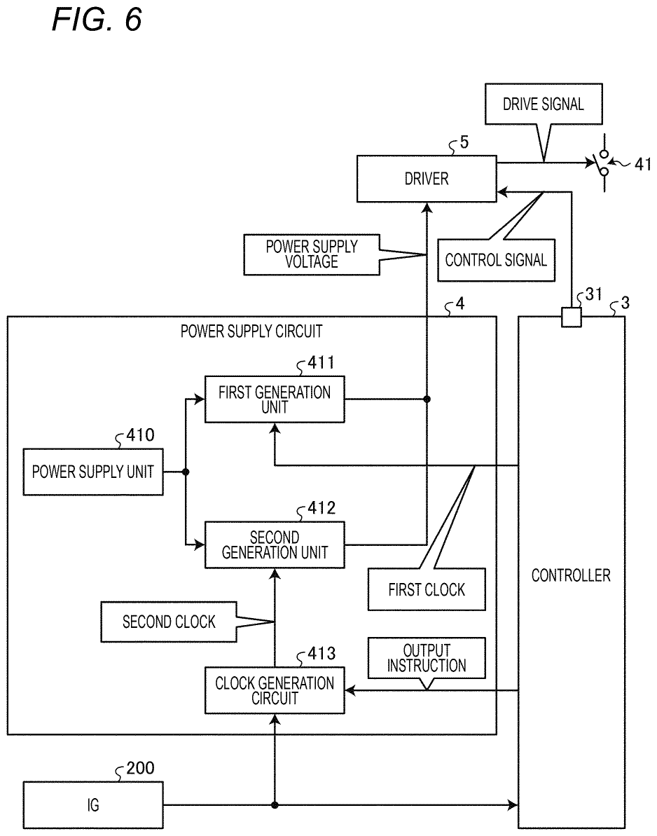

Next, a configuration of the power supply circuit 4 will be specifically described with reference to FIG. 6. FIG. 6 is a diagram illustrating a configuration example of the power supply circuit 4. In the present disclosure, the power supply circuit 4 is configured to generate the first power supply voltage by software processing and the second power supply voltage by a hardware circuit.

Specifically, the power supply circuit 4 includes a power supply unit 410, a first generation unit 411, a second generation unit 412, and the clock generation circuit 413.

The power supply unit 410 supplies a voltage serving as a source of a power supply voltage to the first generation unit 411 and the second generation unit 412. Specifically, the power supply unit 410 supplies electric power supplied from the main power supply 10 or the backup power supply 20 to the first generation unit 411 and the second generation unit 412.

The first generation unit 411 generates the first power supply voltage. Specifically, the first generation unit 411 generates the first power supply voltage by amplifying the voltage supplied from the power supply unit 410 based on the first clock input from the controller 3. That is, the first generation unit 411 generates the first power supply voltage by software processing of the controller 3, more specifically, the first clock output via software processing.

The first clock output from the controller 3 is not always output when the controller 3 is started up, but is output after the initialization processing performed after the controller 3 is started up ends (after first start after the IG 200 is turned on) (the first clock is not output until the initialization processing is completed).

The second generation unit 412 generates the second power supply voltage. Specifically, the second generation unit 412 generates the second power supply voltage by amplifying the voltage supplied from the power supply unit 410 based on the second clock input from the clock generation circuit 413. The clock generation circuit 413 is implemented by a hardware circuit, for example, a crystal oscillator, and generates the second clock and outputs the second clock to the second generation unit 412 when the IG ON signal is input from the IG 200 and the output instruction is issued from the controller 3 to be described later.

The clock generation circuit 413 starts outputting the second clock to the second generation unit 412 when the output instruction configured to be output after the reset confirmation processing is completed is received from the controller 3. Thus, the second power supply voltage is generated after the reset confirmation processing. The processing of outputting the output instruction of the controller 3 is basically performed by a hardware unit provided in the controller 3. The processing of outputting the output instruction of the controller 3 may be configured such that software processing is involved in a part of the process to the extent that it is not affected by the reset. As described above, since the software processing of the controller 3 is not involved in the output of the second clock, the second power supply voltage by the second generation unit 412 is generated without the software processing of the controller 3.

The controller 3 does not output the first clock to the first generation unit 411 until the reset confirmation processing is completed after the controller 3 is started up by turning on the IG 200. After the reset confirmation processing is completed, the controller 3 outputs the first clock to the first generation unit 411. Thus, the first power supply voltage is generated after the reset confirmation processing.

As described above, the controller 3 instructs the power supply circuit 4 to output the power supply voltage after the reset confirmation processing, so that the power supply voltage can be output after the reset confirmation processing by software processing.

Since both the first power supply voltage generated by the first generation unit 411 and the second power supply voltage generated by the second generation unit 412 are generated after the reset confirmation processing is completed (not generated before the reset is started), the supply of the power supply voltage to the driver 5 is started after the reset confirmation processing is completed.

In addition to the configuration illustrated in FIG. 6, for example, an OR circuit to which the first power supply voltage and the second power supply voltage are input may be formed at output stages of the first generation unit 411 and the second generation unit 412, and an AND circuit may be formed at the output stages thereof. In this case, an output destination of the output instruction from the controller 3 is changed, and an output of the OR circuit and the output instruction of the controller 3 are input to the AND circuit. The clock generation circuit 413 is configured to generate the second clock even when there is no output instruction from the controller 3. Accordingly, the controller 3 can output the power supply voltage (the power supply voltage input to the OR circuit) from the AND circuit after the reset confirmation processing by inputting the output instruction to the AND circuit. That is, the power supply circuit 4 uses the AND circuit as a cutoff circuit of the power supply voltage, and cuts off the power supply voltage by the AND circuit until the output instruction is input to the AND circuit (until the reset confirmation processing is completed). The cutoff circuit is not limited to the AND circuit, and any configuration such as a switch can be used as long as the power supply voltage can be cut off. When the cutoff circuit is configured as a switch, the controller 3 outputs a signal for turning on the switch to the switch after the reset confirmation processing is completed.

The power supply circuit 4 may physically delay the output of the power supply voltage by a hardware circuit configuration provided outside the controller 3. This point will be described with reference to FIG. 7.

FIG. 7 is a diagram illustrating another configuration example of the power supply circuit 4. As illustrated in FIG. 7, the power supply circuit 4 further includes the delay circuit 414 as compared with FIG. 6. The delay circuit 414 is a circuit that delays the input of the IG signal received from the IG 200 to the clock generation circuit 413 by a certain period of time (a time set in advance as a time from when the IG signal is turned on to when the reset confirmation processing of the controller 3 is completed). The IG signal is a signal that is output from the IG 200 when the IG 200 is turned on, and is a signal that serves as a trigger for the clock generation circuit 413 to start generating the second clock. That is, the delay circuit 414 delays a timing of the change from OFF to ON of the IG signal. Therefore, the output of the IG signal from the delay circuit 414 indicates that, for example, when the IG signal changes from OFF to ON, the IG signal delayed from the delay circuit 414 changes from OFF to ON. Thus, the delay circuit 414 delays the input of the IG signal to the clock generation circuit 413, thereby delaying the timing at which the clock generation circuit 413 starts generating the second clock. As a result, the second power supply voltage is delayed and output after the reset confirmation processing. The delay circuit 414 can be implemented by, for example, a resistor, but a delay circuit having any configuration can be used.

The controller 3 does not output the first clock to the first generation unit 411 until the reset confirmation processing is completed after the controller 3 is started up by turning on the IG 200. After the reset confirmation processing is completed, the controller 3 outputs the first clock to the first generation unit 411. Thus, the first power supply voltage is generated after the reset confirmation processing.

As described above, since the power supply circuit 4 includes the delay circuit 414 that delays the output of the power supply voltage until after the reset confirmation processing, the power supply voltage can be output after the reset confirmation processing by a hardware circuit without software processing.

The power supply circuit 4 can make the generation of the power supply voltage redundant by generating the first power supply voltage by software processing and the second power supply voltage by the hardware circuit. Accordingly, it is possible to prevent the output of the power supply voltage from the power supply circuit 4 from being interrupted with high accuracy.

FIGS. 6 and 7 illustrate an example in which the power supply circuit 4 generates the first power supply voltage by software processing and the second power supply voltage by the hardware circuit, but the present disclosure is not limited thereto. For example, the power supply circuit 4 may be configured to generate only the first power supply voltage by software processing, or may be configured to generate only the second power supply voltage by a hardware circuit.

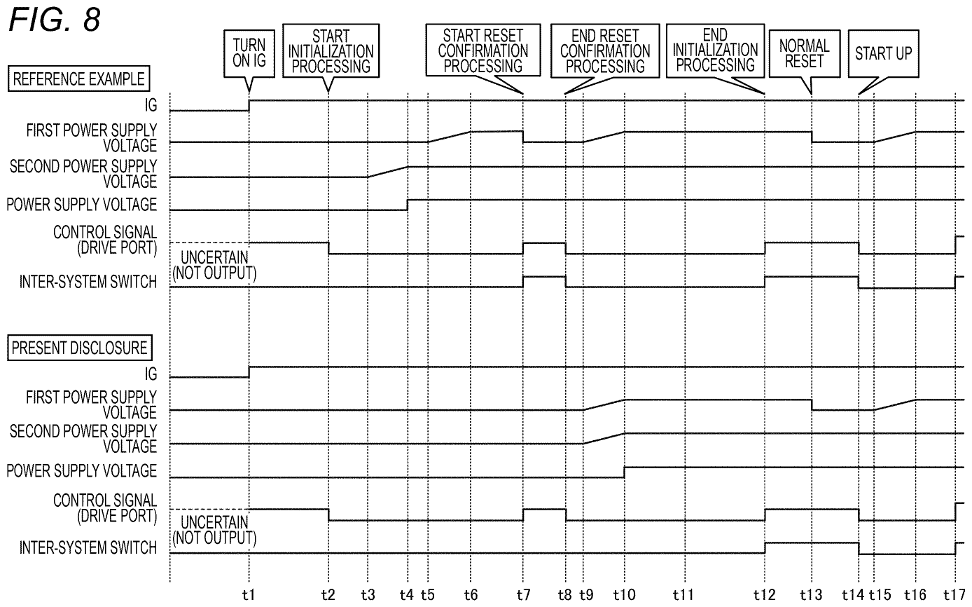

Next, timings of operations of the power supply control device 1 immediately after the IG 200 is turned on will be described with reference to FIG. 8. FIG. 8 is a timing chart illustrating operation timings of the power supply control device 1 immediately after the IG 200 is turned on. FIG. 8 illustrates an operation timing (lower diagram) of the power supply control device 1 according to the present disclosure and an operation timing (upper diagram) of the power supply control device according to a reference example. The power supply control device according to the reference example is configured to output the power supply voltage before the reset confirmation processing.

### Reference Example

In the reference example, the IG 200 is turned on at a time t1, and then the controller 3 is started up and starts the initialization processing at a time t2 after a certain period of time. Further, the power supply circuit 4 starts generating the second power supply voltage by the second generation unit 412 by starting generating the second clock from the clock generation circuit 413 at a time t3 after a certain period of time from when the IG 200 is turned on (the time t1). Thereafter, at a time t4, the duty ratio of the second power supply voltage is stabilized and reaches a voltage value necessary for driving the inter-system switch 41. That is, in the reference example, the power supply voltage is supplied from the power supply circuit 4 to the driver 5 at a time point of the time t4.

The power supply circuit 4 starts generating the first power supply voltage by the first generation unit 411 when the controller 3 starts outputting the first clock at a time t5 after a certain period of time from when the IG 200 is turned on (time t1). Thereafter, at a time t6, the duty ratio of the first power supply voltage is stabilized and reaches a voltage value necessary for driving the inter-system switch 41.

In the reference example, the controller 3 starts the reset confirmation processing at a time t7, and completes the reset confirmation processing at a time t8. That is, the controller 3 performs the reset operation during a period from the time t7 to the time t8. Therefore, the drive port 31 of the controller 3 outputs the ON signal set by default to the driver 5 while the reset operation is being performed. At this time, from the time t7 to the time t8, since the ON signal is input in a state in which the power supply voltage is input, the driver 5 switches the inter-system switch 41 to the turning-on state. After the time t8, the controller 3 outputs the OFF signal from the drive port 31 to resume the initialization processing. That is, the driver 5 switches the inter-system switch 41 to the turning-off state after the time t8. After the time t1, the IG 200 continues to be turned on. Therefore, the second generation unit continues to supply the second power supply voltage for operating the driver 5 after the time t4. Then, at a time t12, the controller 3 ends the initialization processing and outputs the ON signal from the drive port 31. That is, after the time t12, the driver 5 switches the inter-system switch 41 to the turning-on state and shifts to the normal operation.

That is, in the reference example, since the power supply voltage is supplied during the period from the time t7 to the time t8 during which the reset confirmation processing is performed during the period from the time t2 to the time t12 during which the initialization processing is performed, the inter-system switch 41 is temporarily in the turning-on state. That is, the number of times the inter-system switch 41 is turned on/off increases.

### Present Disclosure

On the other hand, in the present disclosure, since the power supply voltage is not supplied during the period from the time t7 to the time t8 during which the reset confirmation processing is performed, the inter-system switch 41 is maintained in the turning-off state. Specifically, in the present disclosure, the first power supply voltage and the second power supply voltage are generated after a time t9 after the reset confirmation processing. The supply of the first power supply voltage is started after the time t9 by preventing the controller 3 from outputting the first clock until the reset confirmation processing ends.

The supply of the second power supply voltage is started after the time t9 by setting the timing of the output instruction from the controller 3 to the clock generation circuit 413 after the reset confirmation processing ends.

Alternatively, the supply of the second power supply voltage is started after the time t9 by delaying the timing of the signal input of the output start of the clock generation circuit 413 by the delay circuit 414 until the reset confirmation processing ends. Therefore, in the present disclosure, from the time t7 to the time t8, the controller 3 outputs the ON signal from the drive port 31, but the power supply voltage is not input to the driver 5, so that the turning-off state of the inter-system switch 41 is maintained. Then, in the present disclosure, the controller 3 ends the initialization processing at the time t12 and outputs the ON signal from the drive port 31. That is, after the time t12, the driver 5 switches the inter-system switch 41 to the turning-on state and shifts to the normal operation.

That is, in the present disclosure, since the power supply voltage is not supplied during the period from the time t7 to the time t8 during which the reset confirmation processing is performed during the period from the time t2 to the time t12 during which the initialization processing is performed, the inter-system switch 41 is maintained in the turning-off state. That is, since the number of times the inter-system switch 41 is turned on/off does not increase, it is possible to prevent the inter-system switch from deteriorating early.

Note that the reference example and the present disclosure perform the same operation after the time t12 after the initialization processing. Specifically, in the reference example and the present disclosure, it is assumed that the controller 3 performs a normal reset operation at a time t13. Unlike the reset confirmation processing performed during the initialization processing, the normal reset operation is reset processing performed when an abnormality of the controller 3 is detected. At a time t14, the reset operation is completed and started. Therefore, during the period from the time t13 to the time t14 during which the reset is performed, the drive port 31 of the controller 3 outputs the ON signal set by default to the driver 5. Further, since the IG 200 continues to be turned on, the second generation unit continues to supply the second power supply voltage for operating the driver 5. Therefore, the ON signal of the inter-system switch 41 is output from the driver 5. That is, since the drive port 31 outputs the ON signal before the time t13, the drive port 31 continues to output the ON signal from the time t13 to the time t14. In addition, from the time t13 to the time t14, the driver 5 receives the ON signal in the state in which the power supply voltage is input, and therefore the turning-on state of the inter-system switch 41 is continued. When the controller 3 is started up at the time t14, the controller 3 outputs the OFF signal from the drive port 31. As a result, the inter-system switch 41 is switched to the turning-off state. That is, in the normal reset operation, the state of the inter-system switch 41 is not switched to OFF→ON→OFF, unlike the reset confirmation processing during the initialization processing of the reference example. Then, the power supply circuit 4 starts generating the first power supply voltage by the first generation unit 411 at a time t15 after a certain period of time from when the controller 3 is started up, and the duty ratio of the first power supply voltage is stabilized and reaches the voltage value necessary for driving the inter-system switch 41 at a time t16. At a time t17 after a certain period of time, the controller 3 outputs the ON signal from the drive port 31 to the driver 5, and switches the inter-system switch 41 to the turning-on state.

Note that, as illustrated in FIG. 8, with respect to the first power supply voltage of the present disclosure, basically, since the output of the first clock is started when the controller 3 is started up, the generation of the first power supply voltage is started when the controller 3 is started up. However, during a period from when the IG 200 is turned on to when the initialization processing is completed, the first clock is not output even when the controller 3 is started up. The clock output is managed and controlled by, for example, a hardware unit capable of continuing management of the stop of the first clock output even when the controller 3 is reset.

With respect to the second power supply voltage, during the normal reset (from the time t13 to the time t14), the IG 200 remains turned on even during reset, and therefore the state in which the second clock is output continues. Once the IG 200 is turned off, the second power supply voltage also goes into the turning-off state, and thereafter, when the IG 200 is changed from the turning-off state to the turning-on state, the processing after the time t1 illustrated in FIG. 8 is performed.

As described above, the power supply control device 1 according to the embodiment includes the inter-system switch 41, the power supply circuit 4, and the controller 3. The inter-system switch 41 is a normally-off type that connects the first system 110 that supplies the electric power of the first power supply (main power supply 10) to the first load 101 and the second system 120 that supplies the electric power of the second power supply (backup power supply 20) to the second load 103. The power supply circuit 4 supplies the power supply voltage for driving the inter-system switch 41. The controller 3 controls the inter-system switch 41, performs the initialization processing at system startup, and performs the reset confirmation processing for resetting itself during the initialization processing. The controller 3 is provided with the drive port 31 set to output the ON signal for turning on the inter-system switch 41 while the reset is being performed, and performs a control to output the OFF signal for turning off the inter-system switch 41 from the drive port 31 during the initialization processing, and notifies the power supply circuit 4 of the output instruction for outputting the power supply voltage after the reset confirmation processing.

According to the present disclosure, the controller 3, which is a computer, notifies the power supply circuit 4 of the output instruction of the power supply voltage after the reset confirmation processing, so that the power supply circuit 4 starts supplying electric power after the reset confirmation processing, and thus the electric power for driving is not supplied to the inter-system switch 41 during the reset confirmation processing. Therefore, while the reset is being performed, the ON signal is output from the drive port 31 of the controller 3, but the electric power for driving the inter-system switch 41 is not supplied, and thus the controller 3 is not turned on. Therefore, the inter-system switch 41 is maintained in the turning-off state even if the reset confirmation processing is performed during the initialization processing. That is, according to the present disclosure, since the turning-off state is maintained during the reset confirmation processing, the number of times the inter-system switch 41 is turned on/off does not increase, and thus it is possible to prevent the inter-system switch 41 from deteriorating early.

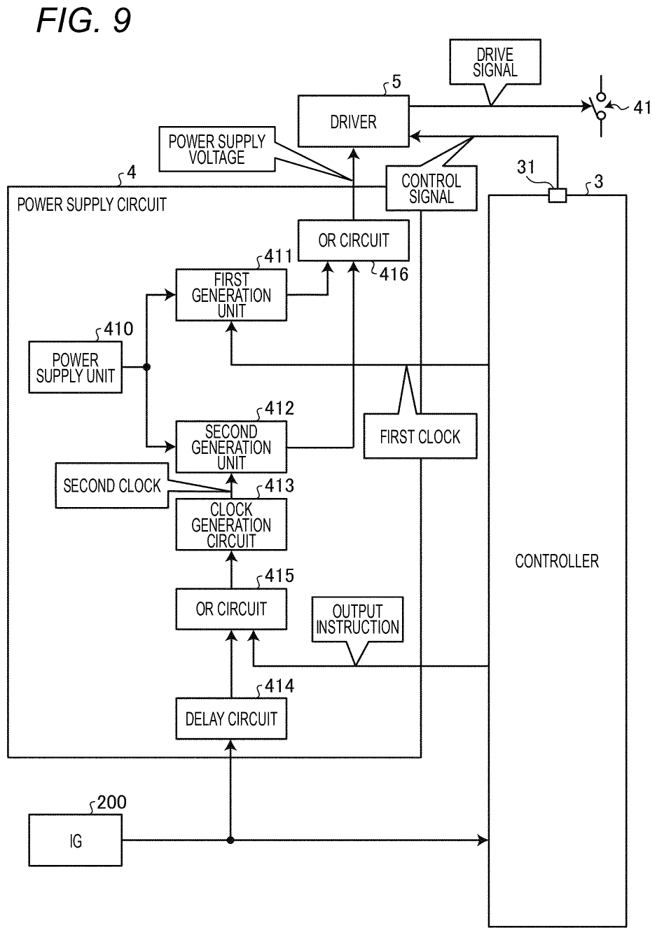

The configuration of the embodiment described above is merely an example, and for example, the configuration described below with reference to FIGS. 9 to 14 can be adopted. FIGS. 9 to 14 are diagrams illustrating the power supply control device 1 according to modifications. Hereinafter, four modifications of first to fourth modifications will be specifically described with reference to FIGS. 9 to 14. In the first to fourth modifications described below, the description of the same configuration as that of the above embodiment may be omitted.

First, the power supply control device 1 according to the first modification will be described with reference to FIGS. 9 to 11. As illustrated in FIG. 9, the first modification is different from the above embodiment in that the power supply circuit 4 further includes two OR circuits 415, 416.

The or circuit 415 is provided between the clock generation circuit 413 and the delay circuit 414.

The OR circuit 415 receives an input of the IG signal delayed by the delay circuit 414 and an input of the output instruction from the controller 3. Specifically, the IG signal is input to the OR circuit 415 after being delayed by the delay circuit 414 until after the reset confirmation processing of the controller 3. The output instruction is the output instruction described with reference to FIG. 6, and in detail, is a signal for instructing the clock generation circuit 413 to start outputting the second clock. The OR circuit 415 instructs the clock generation circuit 413 to output the second clock when at least one of the IG signal or the output instruction input via the delay circuit 414 is input. That is, the clock generation circuit 413 generates a clock signal when at least one of the IG signal or the output instruction is input. It is desirable to start generating the clock signal without delay after the reset confirmation processing is completed, but it is difficult to control a detailed timing in the delay circuit 414. Therefore, it is desirable to generate the clock signal after completion of the reset confirmation processing at an input timing of the output instruction of the controller 3 capable of controlling an output timing in detail. Therefore, a delay time of the delay circuit 414 is set such that the IG signal is output after a sufficient time elapses from the timing when the controller 3 issues the output instruction. In other words, the delay time of the delay circuit 414 is set to a time at which the IG signal is not output from the delay circuit to the OR circuit 415 before the reset confirmation processing is completed even if the time from when the IG is turned on to the completion of the reset confirmation processing varies due to the processing deviation of the controller 3 or the like. That is, the delay time of the delay circuit 414 in the first modification is set to be longer than the delay time of the delay circuit 414 in the embodiment of FIG. 7.

The OR circuit 416 is provided between each of the first generation unit 411 and the second generation unit 412 and the driver 5. When at least one of the first power supply voltage generated by the first generation unit 411 and the second power supply voltage is input, the OR circuit 416 inputs the power supply voltage to the driver 5. The OR circuit 416 may be provided at the same position as that in FIG. 9 also in the embodiment described above, that is, in the configuration illustrated in FIGS. 6 and 7. That is, the OR circuit 416 may be provided at a coupling point where the outputs of the first generation unit 411 and the second generation unit 412 illustrated in FIGS. 6 and 7 are coupled.

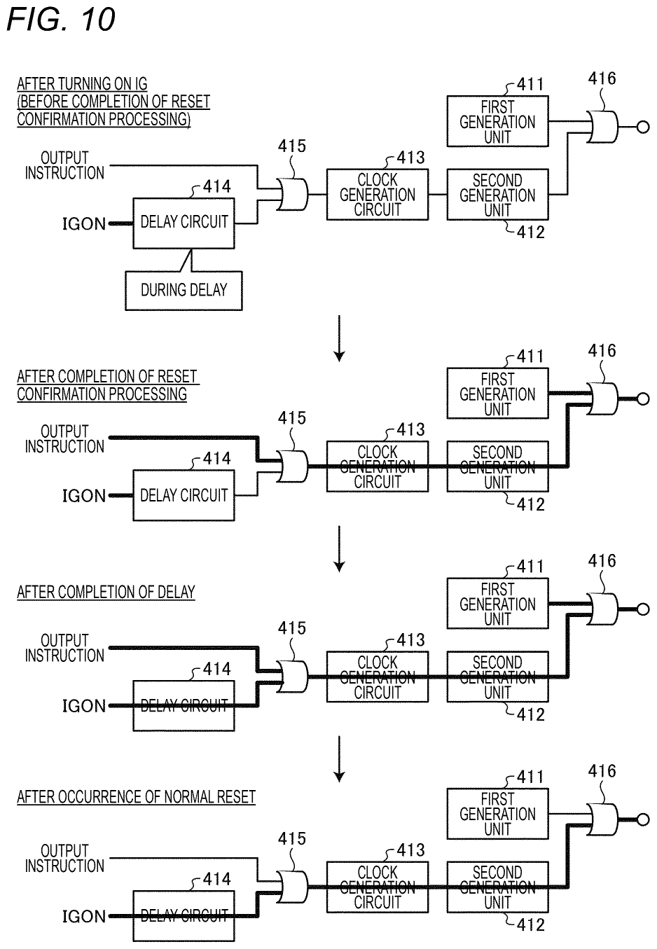

Next, the operation of the power supply control device 1 according to the first modification will be described with reference to FIG. 10. FIG. 10 illustrates the operation immediately after turning on the IG.

### After Turning on IG

As illustrated in FIG. 10, the output instruction is not notified from the controller 3 to the OR circuit 415 before the reset confirmation processing is completed after turning on the IG, that is, during the initialization processing before the reset confirmation processing and the reset confirmation processing. Since the IG signal (IGON) is being delayed by the delay circuit 414, the IG signal (IGON) is not input to the OR circuit 415. As a result, since the second clock is not input to the second generation unit 412, the second power supply voltage is not generated. In addition, since the controller 3 does not output the first clock to the first generation unit 411 until the reset confirmation processing is completed, the first power supply voltage is also not generated. As a result, since the power supply voltage is not input to the driver 5, the normally-off type inter-system switch 41 is turned off.

### After Completion of Reset Confirmation Processing

Next, as illustrated in FIG. 10, after completion of the reset confirmation processing is completed, the controller 3 notifies the OR circuit 415 of the output instruction. Accordingly, the clock generation circuit 413 starts outputting the second clock, and thus the second power supply voltage is generated by the second generation unit 412. Since the IG signal (IGON) is being delayed by the delay circuit 414, the IG signal (IGON) is not input to the OR circuit 415. Since the first clock is input from the controller 3 to the first generation unit 411, the first power supply voltage is also generated. As described above, in the first modification, the controller 3 issues an output instruction after the reset confirmation processing, so that the second power supply voltage can be generated immediately and the inter-system switch 41 can be turned on. Note that, in the present disclosure, since the first power supply voltage is also generated by the first generation unit 411, even if an abnormality or a delay occurs in the generation of the power supply voltage in one of the first generation unit 411 and the second generation unit 412, the power supply voltage can be supplied from the other generation unit, and thus stable supply of the power supply voltage is possible.

### After Completion of Delay

Next, as illustrated in FIG. 10, after completion of the delay by the delay circuit 414, the delayed IG signal is input from the delay circuit 414 to the OR circuit 415. The controller 3 notifies the OR circuit 415 of the output instruction. That is, since the output instruction from the completion of the reset confirmation to the completion of the delay is notified, it is possible to maintain the generation of the second power supply voltage (the inter-system switch 41 can be maintained in the turning-on state) until the IG signal is input to the OR circuit 415.

### After Occurrence of Normal Reset

Next, as illustrated in FIG. 10, when the normal reset occurs during the normal processing after the initialization processing is completed, the output instruction is not notified to the OR circuit 415 because the controller 3 is being reset. On the other hand, the IG signal continues to be input from the delay circuit 414 to the OR circuit 415 even during the reset. Accordingly, since the second power supply voltage can continue to be generated by the IG signal even during the normal reset, the inter-system switch 41 can continue to be turned on.

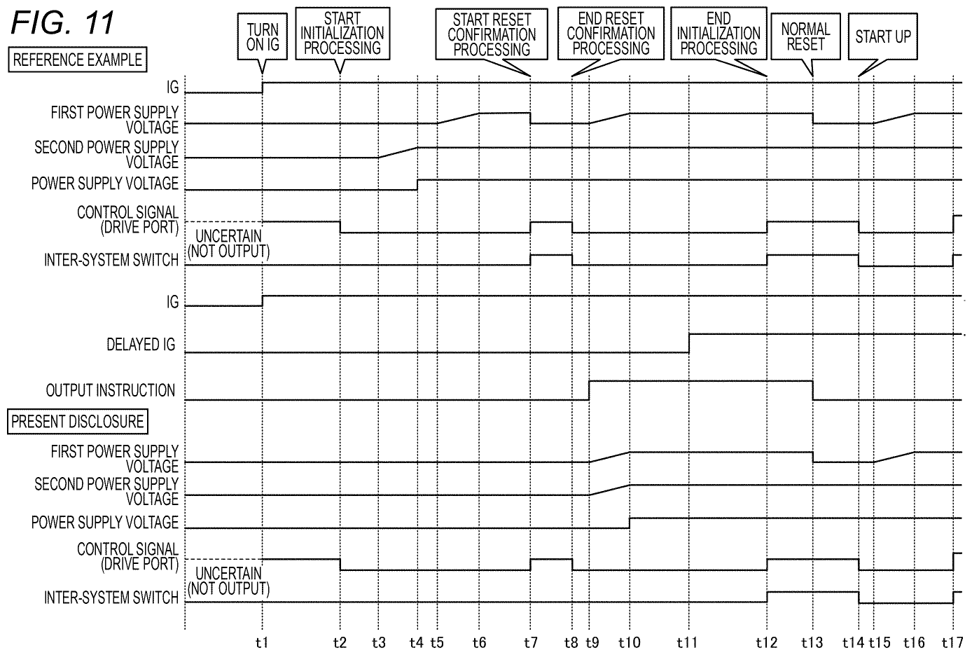

Next, timings of operations of the power supply control device 1 after turning on the IG according to the first modification will be described with reference to FIG. 11. FIG. 11 is a timing chart illustrating operation timings of the power supply control device 1 after turning on the IG according to the first modification. FIG. 11 illustrates an operation timing (lower diagram) of the power supply control device 1 according to the present disclosure and an operation timing (upper diagram) of the power supply control device according to a reference example. The reference example is the same as the reference example described in FIG. 8. In the following description, among the operations illustrated in FIG. 11, the description of the same operations as those illustrated in FIG. 8 may be omitted. In FIG. 11, items of “delayed IG” and “output instruction” are additionally illustrated.

The “delayed IG” is an IG signal delayed by the delay circuit 414. That is, the “delayed IG” indicates a timing at which the IG signal (ON signal) is input to the OR circuit 415. The “output instruction” is an output instruction input from the controller 3 to the OR circuit 415.

As illustrated in FIG. 11, the “delayed IG” is turned on after IG 200 is turned on at the time t1 and is then delayed until a time t11. Once turned on, the “delayed IG” continues to be turned on regardless of whether the controller 3 is reset as long as the IG 200 is turned on.

The output of the “output instruction” is started at the time t9 after the end of the reset confirmation processing. That is, the controller 3 does not output the output instruction until the reset confirmation processing is completed even after the startup at the time t1, and starts the output after end of the reset confirmation processing. As a result, even when ON/OFF of the control signal of the drive port 31 is switched at the timings of the times t2, t7, and t8, the output instruction is stopped and the power supply voltage is not output, so that the drive signal is not output from the driver 5. Therefore, it is possible to avoid unnecessary switching of the turning-on/off state of the inter-system switch 41 at the timings of the times t2, t7, and t8. In FIG. 11, a slight time lag occurs from the end of the reset confirmation processing (time t8) to the start of output of the output instruction (time t9), but this is the time required for the controller 3 to generate and output the output instruction.

As illustrated in FIG. 11, the operation when the normal reset occurs in the controller 3 at the time t13 is the same as that described in FIG. 8. The correspondence between each state illustrated in FIG. 10 and the time in FIG. 11 is as follows. The state after turning on the IG in FIG. 10 occurs at a certain time point between the time t1 and the time t8 in FIG. 11. The stat after completion of the reset confirmation processing of FIG. 10 occurs at a time point near the time t10 of FIG. 11. The state after completion of the delay in FIG. 10 occurs at a certain time point between the time t10 and the time t12 in FIG. 11. The state after the reset in FIG. 10 occurs at a certain time point between the time t13 and the time t16 in FIG. 11.

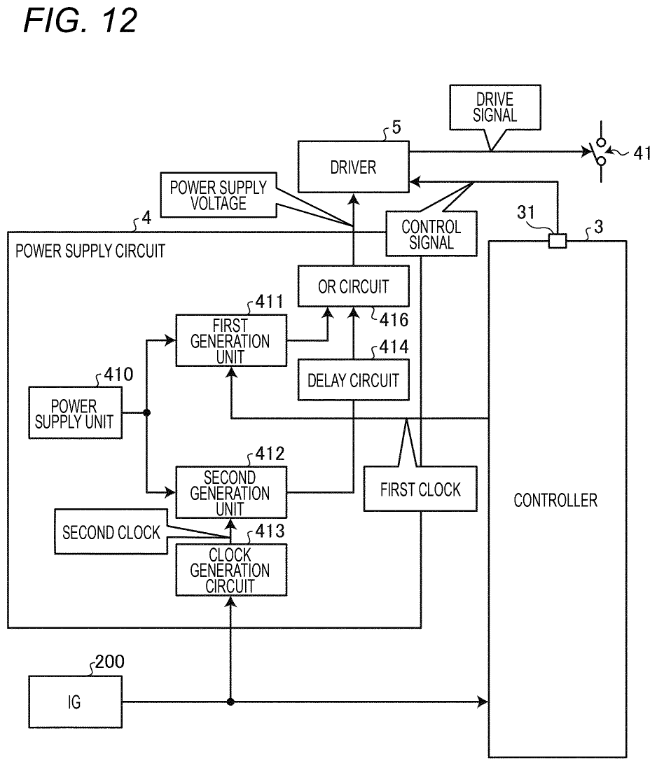

Next, the power supply control device 1 according to the second modification, which is a modification of the embodiment of FIG. 7, will be described with reference to FIG. 12. As illustrated in FIG. 12, in the second modification, a position of the delay circuit 414 is different from that of the embodiment illustrated in FIG. 7.

Specifically, in the second modification, the delay circuit 414 is provided on an output side of the second generation unit 412. Thus, in the second modification, the delay circuit 414 delays the second power supply voltage generated by the second generation unit 412 and outputs the delayed second power supply voltage to the OR circuit 416. Strictly speaking, the delay circuit 414 does not always delay the second power supply voltage input from the second generation unit 412 by a certain period of time, but blocks the supply of the second power supply voltage until a predetermined time (delay time) elapses after the second power supply voltage starts to be input from the second generation unit 412. In other words, the delay circuit 414 blocks the supply of the second power supply voltage from the startup of the IG 200 until the reset confirmation processing is completed, and stops the block after the reset confirmation processing is completed and starts supplying the second power supply voltage. Accordingly, since the second power supply voltage can be prevented from being output before the reset confirmation processing, the inter-system switch 41 can continue to be turned off. That is, unnecessary switching of the inter-system switch 41 can be avoided. Since the second power supply voltage continues to be output after the delay circuit 414 stops the block, even if the controller 3 performs the normal reset, the second power supply voltage continues to be output, and the turning-on state of the inter-system switch 41 can be maintained.

Although FIG. 12 illustrates a configuration in which the delay circuit 414 is provided on the output side of the second generation unit 412, the delay circuit 414 may be provided between the input side of the second generation unit 412 and the clock generation circuit 413. In this case, the delay circuit 414 blocks the clock output for the predetermined time (delay time) after the second clock starts to be input from the clock generation circuit 413, and allows the clock output to pass as it is after the predetermined time elapses.

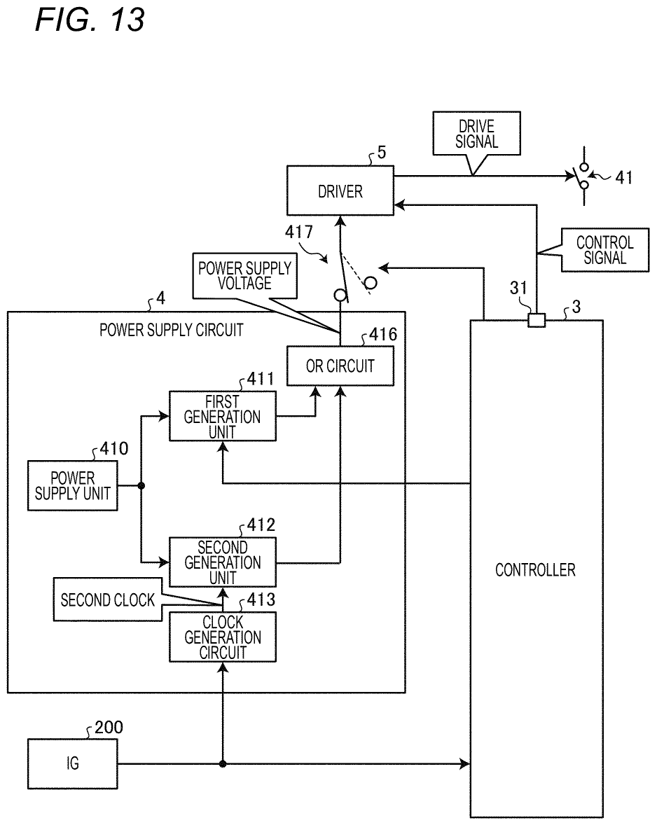

Next, the power supply control device 1 according to the third modification, which is a modification of the embodiment of FIG. 6, will be described with reference to FIG. 13. As illustrated in FIG. 13, the third modification is different from the embodiment described above of FIG. 6 in that the output instruction from the controller 3 is output as a switching signal of an additionally provided power supply path switch 417.

The power supply path switch 417 is a switch that connects a supply path of the power supply voltage from the power supply circuit 4 to the inter-system switch 41. Specifically, the power supply path switch 417 connects or cuts off a supply path between the OR circuit 416 and the driver 5. Hereinafter, connecting the supply path of the power supply voltage is referred to as “ON”, and cutting off the supply path is referred to as “OFF”.

In the third modification, turning on/off of the power supply path switch 417 is controlled by the controller 3.

First, the power supply path switch 417 is turned off in an initial state. Then, the controller 3 cuts off the supply of the second power supply voltage by turning off the power supply path switch 417 until the reset confirmation processing is completed after the startup of the IG 200. Since the initial state of the power supply path switch 417 is in the turning-off state, the power supply path switch 417 continues to be in the turning-off state while the controller 3 is being reset. Then, the controller 3 outputs an output instruction to the power supply path switch 417 after the reset confirmation processing is completed. That is, the controller 3 starts supplying the second power supply voltage by outputting an ON signal to the power supply path switch 417 to turn on the power supply path switch 417. Accordingly, since the second power supply voltage can be prevented from being output before the reset confirmation processing, the inter-system switch 41 can continue to be turned off. That is, unnecessary switching of the inter-system switch 41 can be avoided. The power supply path switch 417 may be configured as a normally-off type switch in which the state of the switch is in the turning-off state when the power supply is turned off (IG OFF), in other words, when a signal for controlling the state of the switch is not input.

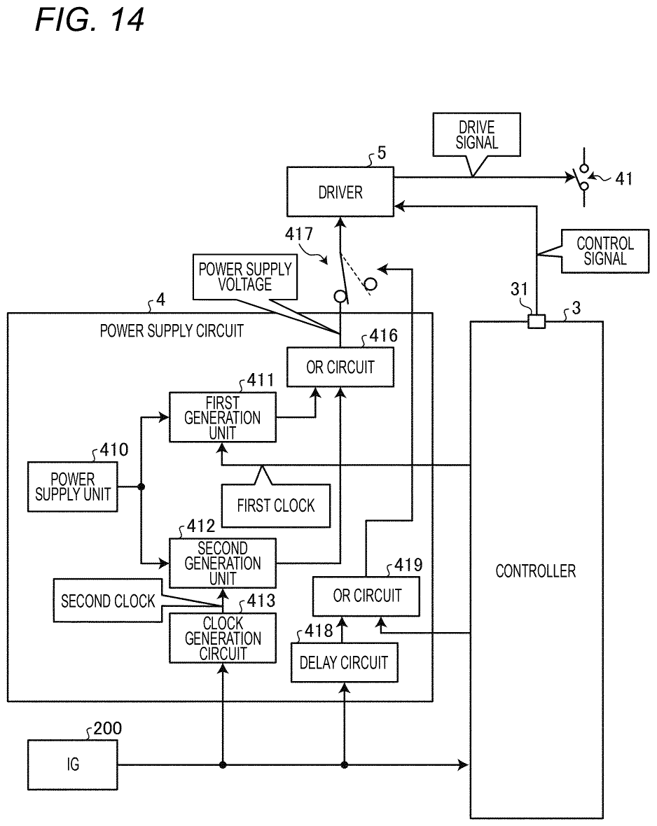

Although FIG. 13 illustrates an example in which the controller 3 controls the power supply path switch 417, the power supply path switch 417 may be controlled by the IG signal. This point will be described with reference to FIG. 14.

The power supply control device 1 according to the fourth modification, which is a modification of the first modification of FIG. 9, will be described with reference to FIG. 14. In the fourth modification, a connection destination of an OR circuit 419 (415) to which an output of a delay circuit 418 (414) and the output instruction from the controller 3 are input is changed from the first modification.

In the first modification, the output of the OR circuit 415 is input to the clock generation circuit 413, but in the fourth modification, the output of the OR circuit 419 is input to the power supply path switch 417 as a switching signal. The power supply path switch 417 is the same as that described in the third modification of FIG. 13.

The delay circuit 418 receives the IG signal from the IG 200, delays the IG signal by a predetermined time, and outputs the IG signal to the OR circuit 419. Specifically, the delay circuit 418 delays the IG signal to the same timing as in the first modification of FIG. 9. The delayed IG signal becomes an ON signal for turning on the power supply path switch 417.

As in the first modification of FIG. 9, the controller 3 outputs, to the OR circuit 419, an ON signal for turning on the power supply path switch 417 after the reset confirmation processing is completed.

The OR circuit 419 receives the IG signal (ON signal) delayed by the delay circuit 418 and the ON signal from the controller 3. When at least one of the ON signal of the controller 3 or the ON signal of the delay circuit 418 is input, the OR circuit 419 outputs the ON signal to the power supply path switch 417. As a result, the power supply path switch 417 changes from the turning-off state in the initial state to the turning-on state, and starts inputting the power supply voltage to the driver 5.

In this way, the power supply path switch 417 can be turned on immediately after the reset confirmation processing by the output instruction of the ON signal of the controller 3. In addition, the ON signal of the controller 3 continues to be output until the IG signal delayed by the delay circuit 418 is output after the power supply path switch 417 is turned on, so that the turning-on state of the power supply path switch 417 can be maintained until the IG signal is input to the OR circuit 419. After the IG signal is input by the delay circuit 418, the ON signal of the controller 3 may be stopped. Accordingly, it is possible to reduce a processing load of the controller 3 while maintaining the power supply path switch 417 in the turning-on state.

In FIGS. 13 and 14, the power supply path switch 417 may be provided in the power supply circuit 4. In FIG. 14, the power supply path switch 417, the delay circuit 418, and the OR circuit 419 may be a switching circuit. The switching circuit may be provided within the power supply circuit 4, or may be provided separately from the power supply circuit 4.

In the embodiment and modifications described above, the initialization processing and the reset confirmation processing are described as separate processing, but the reset confirmation processing may be one of a plurality of types of processing performed as the initialization processing. Although the reset confirmation processing is described as being performed during the initialization processing, the reset confirmation processing may be performed at the beginning or the end of the initialization processing. An output state of the drive signal in this case is “OFF→ON→OFF” when the reset processing is performed in the middle, whereas the output state is “ON→OFF” or “OFF→ON” when the reset processing is performed first or last, and the number of times of switching of the state of the signal for controlling the switch decreases, but the switching also occurs, and thus the content of the present disclosure is effective.

The delay circuit and the OR circuit described in the embodiment and modifications described above may be separately provided outside the power supply circuit 4.

Further effects and modifications may be easily derived by those skilled in the art. For this reason, broader aspects of the present disclosure are not limited to the specific details and the representative embodiment illustrated and described above. Therefore, various modifications can be made without departing from the spirit or scope of the general inventive concept as defined by the appended claims and equivalents thereof.

### Appendix

According to another aspect of the present disclosure, there is provided a power supply control device including:
a normally-off type inter-system switch configured to connect a first system that supplies electric power of a first power supply to a first load and a second system that supplies electric power of a second power supply to a second load;
a driver configured to output a drive signal to the inter-system switch;
a power supply circuit configured to supply a power supply voltage for operating the driver; and
a computer configured to control the inter-system switch, perform initialization processing at system startup and perform reset confirmation processing for resetting the computer during the initialization processing,
in which the computer has a drive port set to output, to the driver, an ON signal for turning on the inter-system switch while the reset is being performed,
in which the computer performs a control to output an OFF signal for turning off the inter-system switch from the drive port to the driver during the initialization processing,
in which the computer issues an output instruction to the power supply circuit in response to the reset confirmation processing being completed, and
in which the power supply circuit starts supplying the power supply voltage in response to at least one of a system startup signal and the output instruction being input, the system startup signal being delayed by a delay circuit that delays the system startup signal until completion of the reset confirmation processing.

According to another aspect of the present disclosure, there is provided a power supply control device including:
a normally-off type inter-system switch configured to connect a first system that supplies electric power of a first power supply to a first load and a second system that supplies electric power of a second power supply to a second load;
a driver configured to output a drive signal to the inter-system switch;
a power supply circuit configured to supply a power supply voltage for operating the driver;
a power supply path switch provided in a supply path of the power supply voltage to the driver and configured to cut off the supply path at system startup; and
a computer configured to control the inter-system switch, perform initialization processing at the system startup and perform reset confirmation processing for resetting the computer during the initialization processing,
in which the computer has a drive port set to output an ON signal for turning on the inter-system switch while the reset is being performed,
in which the computer performs a control to output an OFF signal for turning off the inter-system switch from the drive port to the driver during the initialization processing, and
in which the computer issues an output instruction to the power supply path switch to connect the supply path in response to the reset confirmation processing being completed.

According to another aspect of the present disclosure, there is provided a power supply control device including:
a normally-off type inter-system switch configured to connect a first system that supplies electric power of a first power supply to a first load and a second system that supplies electric power of a second power supply to a second load;
a driver configured to output a drive signal to the inter-system switch;
a power supply circuit configured to supply a power supply voltage for operating the driver;
a switching circuit including a power supply path switch that is provided in a supply path of the power supply voltage to the driver and cuts off the supply path at system startup; and
a computer configured to control the inter-system switch, perform initialization processing at the system startup and perform reset confirmation processing for resetting the computer during the initialization processing,
in which the computer has a drive port set to output an ON signal for turning on the inter-system switch while the reset is being performed,
in which the computer performs a control to output an OFF signal for turning off the inter-system switch from the drive port during the initialization processing,
in which the computer issues an output instruction to the power supply circuit to cause the driver to start supplying the power supply voltage in response to the reset confirmation processing being completed, and
in which the switching circuit switches the power supply path switch so that the supply path is connected, in response to at least one of a system startup signal and the output instruction being input, the system startup signal being delayed by a delay circuit that delays the system startup signal until completion of the reset confirmation processing.

What is claimed is:

1. An in-vehicle control device, for a normally-off type inter-system switch disposed between a first system and a second system, comprising:
a driver configured to output an ON or OFF signal to the inter-system switch; and
a computer configured to perform self-reset operation check upon an ignition ON of a vehicle, then to initiate supplying a power supply voltage and outputting the ON signal to the driver upon completion of the self-reset operation check.

2. An in-vehicle control device comprising:
a normally-off type inter-system switch configured to connect a first system that supplies electric power of a first power supply to a first load and a second system that supplies electric power of a second power supply to a second load;
a driver configured to output an ON or OFF signal to the inter-system switch;
a power supply circuit configured to supply a power supply voltage for operating the driver; and
a computer configured to control the inter-system switch, perform initialization processing at system startup and perform self-reset operation check for performing self-reset of the computer during the initialization processing,
wherein the computer has a drive port set to output, to the driver, an ON signal for turning on the inter-system switch while the self-reset is being performed,
wherein the computer performs a control to output an OFF signal for turning off the inter-system switch from the drive port to the driver during the initialization processing, and
wherein the computer issues an output instruction to the power supply circuit to start supplying the power supply voltage to the driver in response to the self-reset operation check being completed.

3. An in-vehicle control device comprising:
a normally-off type inter-system switch configured to connect a first system that supplies electric power of a first power supply to a first load and a second system that supplies electric power of a second power supply to a second load;
a driver configured to output an ON or OFF signal to the inter-system switch;
a power supply circuit configured to supply a power supply voltage for operating the driver; and
a computer configured to control the inter-system switch, perform initialization processing at system startup and perform self-reset operation check for performing self-reset of the computer during the initialization processing,
wherein the computer has a drive port set to output, to the driver, an ON signal for turning on the inter-system switch while the self-reset is being performed,
wherein the computer performs a control to output an OFF signal for turning off the inter-system switch from the drive port to the driver during the initialization processing, and
wherein the power supply circuit includes a delay circuit that delays start of supply of the power supply voltage after the system startup until completion of the self-reset operation check.

4. The in-vehicle control device according to claim 2,
wherein the power supply circuit starts supplying the power supply voltage in response to at least one of a system startup signal and the output instruction being input, the system startup signal being delayed by a delay circuit that delays the system startup signal until completion of the self-reset operation check.

5. The in-vehicle control device according to claim 4,
wherein a delay time of the delay circuit is set to a time at which the system startup signal is input after the output instruction is input to the power supply circuit.

6. The in-vehicle control device according to claim 2,
wherein the power supply circuit starts generating a clock signal by a clock generation circuit and generates the power supply voltage based on the clock signal, in response to the output instruction being input.

7. The in-vehicle control device according to claim 3,
wherein the power supply circuit starts generating a clock signal by a clock generation circuit and generates the power supply voltage based on the clock signal, in response to a system startup signal being input from the delay circuit.

8. The in-vehicle control device according to claim 4,
wherein the power supply circuit starts generating a clock signal by a clock generation circuit and generates the power supply voltage based on the clock signal, in response to at least one of the output instruction and a system startup signal delayed from the delay circuit being input.

9. The in-vehicle control device according to claim 3,
wherein the power supply circuit continues to supply the power supply voltage to the driver based on a system startup signal continuously input from the delay circuit while normal self-reset that is generated after the initialization processing is completed is being performed.

10. The in-vehicle control device according to claim 4,
wherein the power supply circuit continues to supply the power supply voltage to the driver based on a system startup signal continuously input from the delay circuit while normal self-reset that is generated after the initialization processing is completed is being performed.

11. The in-vehicle control device according to claim 2,
wherein the first load and the second load are devices mounted on a vehicle.

12. The in-vehicle control device according to claim 3,
wherein the first load and the second load are devices mounted on a vehicle.
